(19) United States
(12) Patent Application Publication
(10) Pub. No.: US 2026/0193079 A1
(43) Pub. Date: Jul. 9, 2026

(54) MICRO-ELECTRO-MECHANICAL SYSTEM PACKAGE AND FABRICATION METHOD THEREOF

(71) Applicant: Vanguard International Semiconductor Corporation, Hsinchu (TW)

(72) Inventor: RANGANATHAN NAGARAJAN, Singapore (SG)

(73) Assignee: Vanguard International Semiconductor Corporation, Hsinchu (TW)

(21) Appl. No.: 19/012,921

(22) Filed: Jan. 8, 2025

(51) Int. Cl. B81B 7/00; B81B 3/00; B81C 1/00; H01L 23/26

(52) U.S. Cl. CPC B81B 7/0038; B81B 3/0021; B81C 1/00285; H10W 76/48; B81B 2201/0242

(57) ABSTRACT

A MEMS package includes a first substrate, an interconnect layer, a getter structure, a MEMS device layer and a second substrate. The interconnect layer is disposed on the first substrate. The getter structure is disposed in both the interconnect layer and the first substrate. The getter structure includes multiple trenches and a getter layer. These trenches pass through the interconnect layer and extend downwards into the first substrate. The getter layer is conformally disposed in these trenches and on the interconnect layer. The MEMS device layer is bonded to the interconnect layer. The second substrate includes a cavity and is bonded to the MEMS device layer.

### BACKGROUND OF THE INVENTION

### 1. Field of the Invention

The present disclosure relates generally to micro-electro-mechanical system (MEMS) packages, and more particularly to MEMS packages including a getter structure, and fabrication methods thereof.

### 2. Description of the Prior Art

Micro-electro-mechanical system (MEMS) devices are microscopic devices that integrate mechanical and electrical components to sense physical quantities and/or to interact with the surrounding environment. MEMS devices, for example, accelerometers, gyroscopes, pressure sensors and microphones, have become widespread in many electronic products, such as tablet computers, automobiles, and smartphones. The gyroscopes require high-vacuum encapsulation to achieve a high Q factor. High vacuum may be achieved by creating deep cavities, exceeding 100 μm in depth, in the cap wafer or by using a getter in MEMS packages to absorb outgassed gases from MEMS devices. However, in conventional MEMS packages, the depth of the cavities and the getters cannot fully satisfy the requirements of MEMS devices for high vacuum and optimal performance.

### SUMMARY OF THE INVENTION

In view of this, the present disclosure provides micro-electro-mechanical system (MEMS) packages and fabrication methods thereof to enhance the getter absorption area of a getter structure without increasing the cavity depth in a cap wafer. The getter structure has a high aspect ratio and is integrated into an interconnect layer and a complementary metal-oxide-semiconductor (CMOS) wafer. The getter structure can enhance the getter's absorption area for the high-vacuum requirements of MEMS devices, such as gyroscopes.

According to an embodiment of the present disclosure, a MEMS package is provided and includes a first substrate, an interconnect layer, a getter structure, a MEMS device layer and a second substrate. The interconnect layer is disposed on the first substrate. The getter structure is disposed in both the interconnect layer and the first substrate. The getter structure includes a plurality of trenches and a getter layer. The plurality of trenches pass through the interconnect layer and extend downwards into the first substrate. The getter layer is conformally disposed in the plurality of trenches and on the interconnect layer. The MEMS device layer is bonded to the interconnect layer. The second substrate includes a cavity and is bonded to the MEMS device layer.

According to an embodiment of the present disclosure, a method of fabricating a MEMS package is provided and includes the following steps. A first substrate is provided, and an interconnect layer is formed on the first substrate. A getter structure is formed in the interconnect layer and the first substrate. A second substrate is provided with a cavity formed therein. A MEMS device layer is formed, bonded to the second substrate, and covers the cavity. In addition, the MEMS device layer is bonded to the interconnect layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a MEMS package according to one embodiment of the present disclosure.

FIG. 2 shows schematic top views of several getter structures in MEMS packages according to some embodiment of the present disclosure.

FIG. 3, FIG. 4, FIG. 5, FIG. 6, FIG. 7 and FIG. 8 are schematic cross-sectional views of some stages of a method of fabricating a MEMS package according to one embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “under” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first”, “second”, and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that may vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure is directed to MEMS packages and fabrication methods thereof. The MEMS packages include a getter structure with a high aspect ratio greater than 5. The getter structure can enhance the surface area of the getter material for effective gas absorption during getter activation, thereby satisfying the high-vacuum requirements of MEMS devices. The getter structure includes multiple trenches and a getter layer. These trenches are formed by etching to pass through an interconnect layer and extend downward into a complementary metal-oxide-semiconductor (CMOS) wafer, thereby achieving a high aspect ratio. The getter layer is conformally formed in these trenches and on the interconnect layer, thereby enhancing the getter absorption area to achieve a high vacuum for MEMS devices such as gyroscopes.

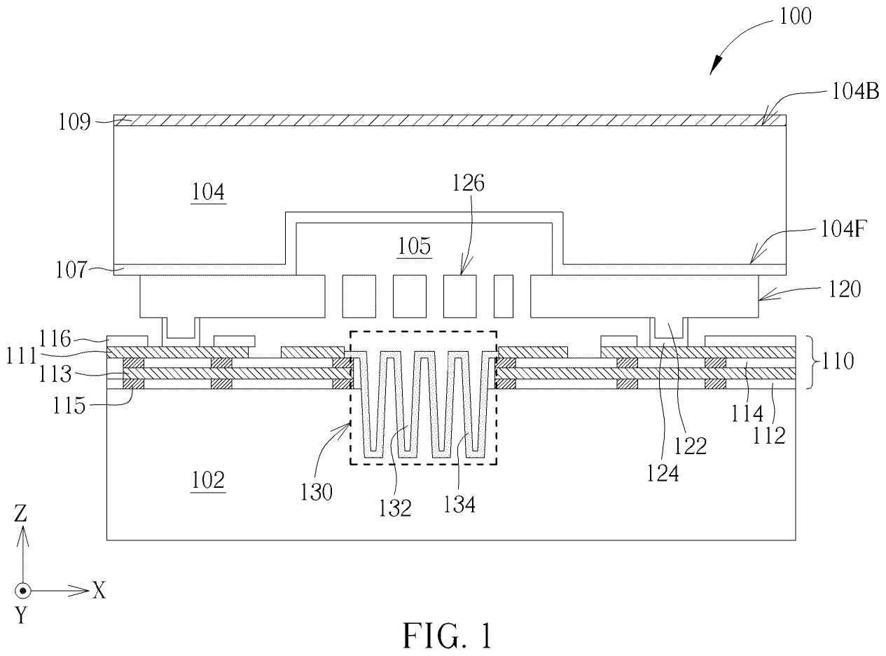

FIG. 1 is a schematic cross-sectional view of a MEMS package 100 according to one embodiment of the present disclosure. The MEMS package 100 includes a first substrate 102, an interconnect layer 110, a getter structure 130, a MEMS device layer 120 and a second substrate 104. The first substrate 102 may be a silicon wafer and includes multiple CMOS transistors or other elements formed therein. The interconnect layer 110 is disposed on the first substrate 102. The interconnect layer 110 includes multiple metal layers, multiple inter-metal dielectric (IMD) layers, and multiple vias in the IMD layers to connect two metal layers.

In the interconnect layer 110, the metal layers at least include a top metal layer 111 and a second-to-last metal layer 113. The IMD layers at least include a first IMD layer 112 and a second IMD layer 114. The first IMD layer 112 is disposed on the first substrate 102, and the second-to-last metal layer 113 is formed on the first IMD layer 112. Some vias 115 are formed in the first IMD layer 112 and electrically connect to the CMOS transistors in the first substrate 102 and the second-to-last metal layer 113. The second IMD layer 114 is formed on the first IMD layer 112 to cover the second-to-last metal layer 113. The top metal layer 111 is formed on the second IMD layer 114, such that the second IMD layer 114 is disposed between the top metal layer 111 and the second-to-last metal layer 113. Some other vias 115 are formed in the second IMD layer 114 to electrically connect to the top metal layer 111 and the second-to-last metal layer 113. Therefore, the interconnect layer 110 is electrically coupled to the CMOS transistors formed in the first substrate 102. Furthermore, the interconnect layer 110 includes a passivation layer 116 disposed on the top metal layer 111. The passivation layer 116 has several openings to expose portions of the top metal layer 111 for seal ring bonding, bond pads, and corresponding MEMS devices.

As shown in FIG. 1, the MEMS device layer 120 is bonded to the interconnect layer 110. The MEMS device layer 120 includes a seal ring 122 bonded to the top metal layer 111 with a eutectic bonding material 124. The seal ring 122 is a standoff structure protruding towards the interconnect layer 110. The seal ring 122 is integrated into and has the same composition as the MEMS device layer 120. In some embodiments, the composition of the MEMS device layer 120 may be doped silicon or doped polysilicon. The eutectic bonding material 124 may include germanium (Ge) and aluminum (Al). Furthermore, the MEMS device layer 120 includes features such as trenches, cantilever beams, membranes, and proof masses to construct a MEMS device 126, for example, a gyroscope, or other MEMS device requiring high vacuum.

The second substrate 104 is bonded to the MEMS device layer 120 through a bonding layer 107, for example, a silicon oxide layer. The second substrate 104 may be a silicon wafer and has a front surface 104F opposite to a back surface 104B. A cavity 105 is formed in and near the front surface 104F of the second substrate 104. The cavity 105 is located directly above the MEMS device 126. The bonding layer 107 is disposed between the MEMS device layer 120 and the second substrate 104, and may be further conformally extended into the cavity 105. Moreover, a metal layer 109 may be formed on the back surface 104B of the second substrate 104. The metal layer 109 may be an aluminum layer for electromagnetic wave shielding such as radio frequency (RF) shielding and/or electrical grounding.

According to embodiments of the present disclosure, the getter structure 130 is disposed in the interconnect layer 110 and the first substrate 102. The getter structure 130 includes multiple trenches 132 and a getter layer 134. The trenches 132 are formed by etching to pass through the interconnect layer 110 and extend downward into the first substrate 102, thereby achieving a high aspect ratio, for example, 5 to 20. In some embodiments, the depth of the trenches 132 may be about 5 μm to about 10 μm. The getter layer 134 is conformally formed in the trenches 132 and on the interconnect layer 110. The getter layer 134 is a continuous thin film in the getter structure 130. In some embodiments, the thickness of the getter layer 134 may be about 1 μm to about 2 μm. The getter structure 130 has an aspect ratio substantially the same as that of the trenches 132, for example, about 5 to 20. The getter structure 130 with high aspect ratio can enhance the getter absorption area for effective gas absorption during getter activation. The outgassed gases from the MEMS device layer 120, the interconnect layer 110, and the first substrate 102, and the gases in the cavity 105, are effectively absorbed by the getter structure 130, thereby enhancing the vacuum degree for the MEMS device 126 application.

In some embodiments, the composition of the getter layer 134 may be Ti, a Ti-based alloy, a Zr-based alloy, a Zr—V-based alloy, a Zr—Co-based alloy or other suitable material for absorbing gases in the MEMS package 100. The getter material for the getter layer 134 may be chosen based on the vacuum requirements for the MEMS device 126 application. The Ti-based alloy is for example Ti—Zr, Ti—Mo or Ti—Zr—V. The Zr-based alloy is for example Zr—Al, Zr—C or Zr—Fe. The Zr—V-based alloy is for example Zr—V—Fe or Zr—V—Mn. The Zr—Co-based alloy is for example Zr—Co, Zr—Co—Ce or Zr—Co—La. The getter layer 134 is activated to absorb gases such as H₂, N₂, CO, CO₂ or H₂O in the MEMS package 100. Moreover, the MEMS device layer 120 is bonded to the interconnect layer 110 at a bonding temperature, and the getter structure 130 has a getter activation temperature lower than or equal to the bonding temperature. For example, the MEMS device layer 120 may be bonded to the interconnect layer 110 by eutectic bonding at about 450° C., and the getter structure 130 may be activated at about 150° C. to about 450° C. Therefore, the getter structure 130 is simultaneously activated during the bonding process of the MEMS device layer 120 to the interconnect layer 110.

As shown in FIG. 1, the getter structure 130 is located directly below the MEMS device 126 such as a gyroscope requiring high vacuum encapsulation. Moreover, the getter structure 130 is located directly below the cavity 105 of the second substrate 104. After the MEMS device layer 120 is bonded to the interconnect layer 110, the getter structure 130 is activated to absorb gases in the cavity 105, thereby reducing the pressure in the cavity 105 to provide high vacuum for the MEMS device 126. Furthermore, the getter layer 134 is activated to absorb the outgassed gases from the MEMS device 126, the interconnect layer 110, and the first substrate 102. The getter structure 130 has a high aspect ratio to enhance the getter absorption area, thereby efficiently absorbing the gases in the MEMS package 100 and providing a high vacuum, which is beneficial for gyroscope applications.

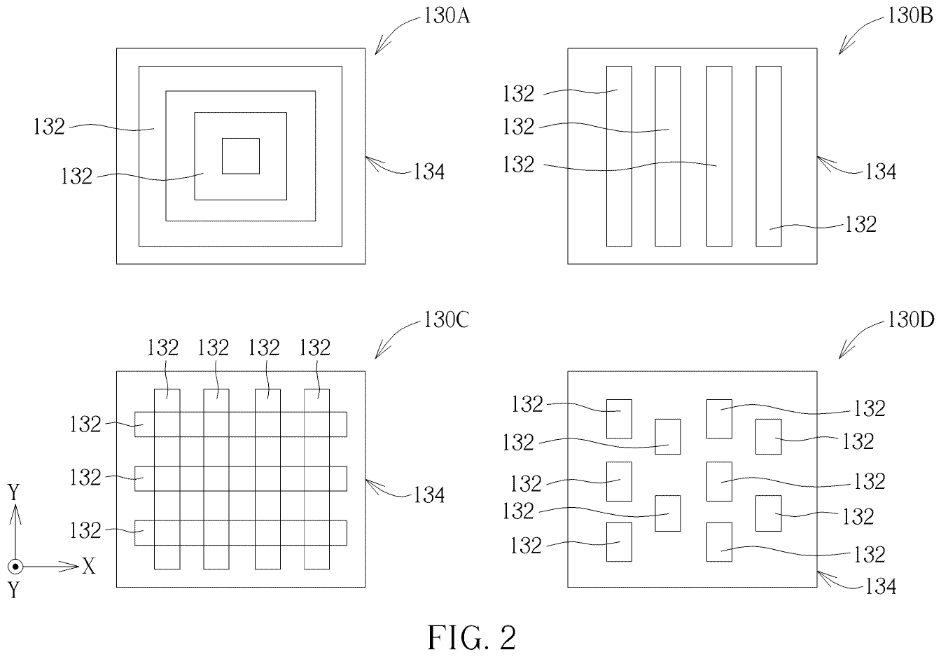

FIG. 2 shows schematic top views of several getter structures 130A, 130B, 130C, and 130D in MEMS packages 100 according to some embodiments of the present disclosure. In one embodiment, the getter structure 130A includes multiple annular trenches 132 arranged concentrically. In another embodiment, the getter structure 130B includes multiple striped trenches 132, all extending along a first direction (e.g., the Y-axis) and arranged in a second direction (e.g., the X-axis). In further another embodiment, the getter structure 130C includes multiple striped trenches 132 arranged in columns and rows that intersect each other. In another embodiment, the getter structure 130D includes multiple short trenches 132 arranged in a series of different positions, with a staggered layout. All the getter structures 130A, 130B, 130C and 130D include the getter layer 134 conformally formed in the trenches 132 and on an area of the interconnect layer 110. The getter layer 134 is a continuous thin film in the getter structures 130A, 130B, 130C and 130D. The aforementioned layouts of the trenches 132 are illustrated as examples, but are not limited thereto. The getter structure 130 may have multiple trenches 132 or multiple openings of other shapes and/or arrangements to enhance the getter absorption area.

In addition, as shown in FIG. 1, the getter structure 130 is formed in an area of the interconnect layer 110. In one embodiment, this area of the interconnect layer 110 includes multiple IMD layers without the metal layers. For example, in this area, the first IMD layer 112 and the second IMD layer 114 are stacked directly without the top metal layer 111 and the second-to-last metal layer 113. In one embodiment, the getter structure 130 is formed in the interconnect layer 110 to pass through the IMD layers without traversing the metal layers. In another embodiment, the getter structure 130 is formed in the interconnect layer 110 to pass through the IMD layers and the top metal layer without traversing other metal layers. Moreover, the getter layer 134 may be in direct contact with the top metal layer 111 abutting the getter structure 130. Therefore, the getter structure 130 may be electrically connected to the interconnect structure 110 through the top metal layer 111.

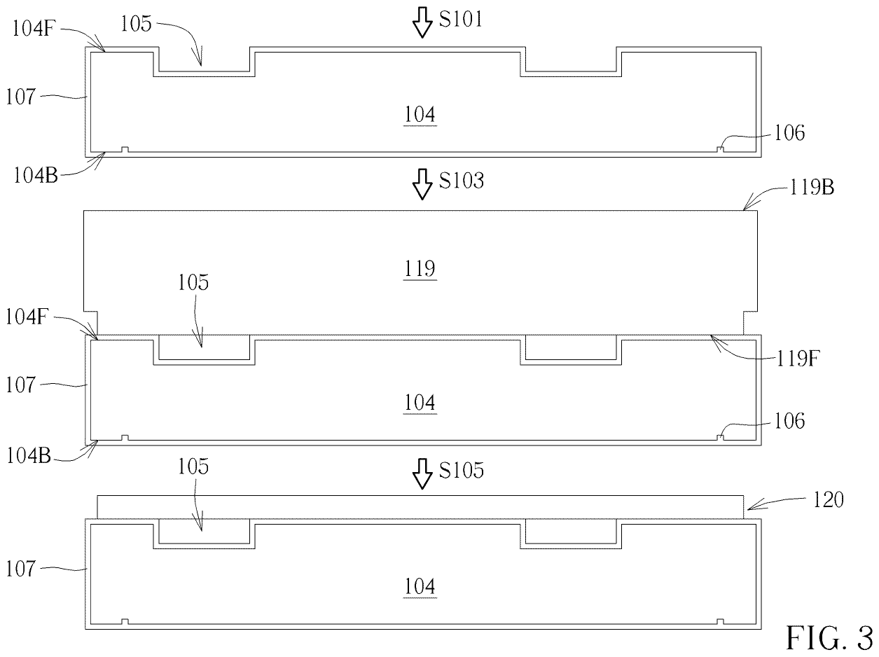

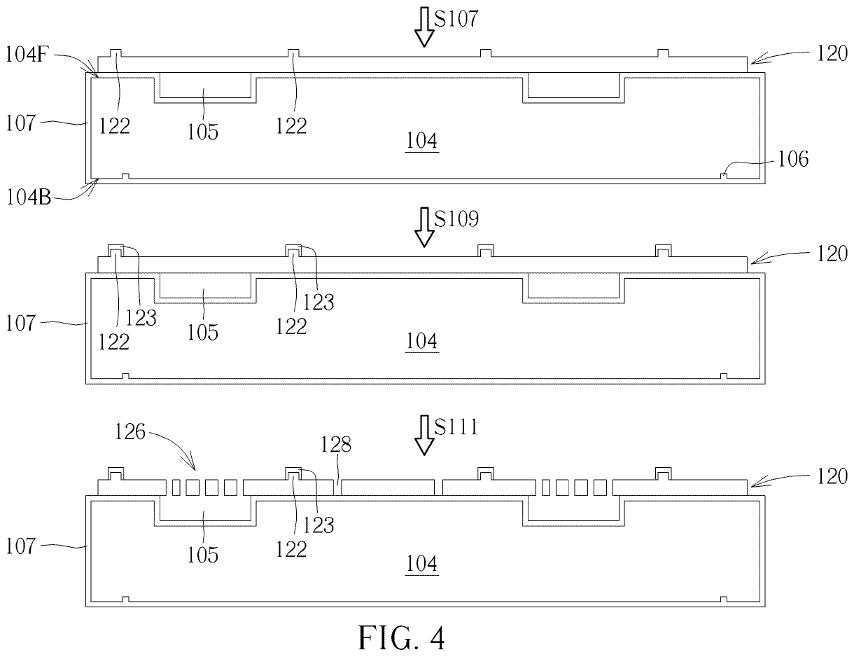

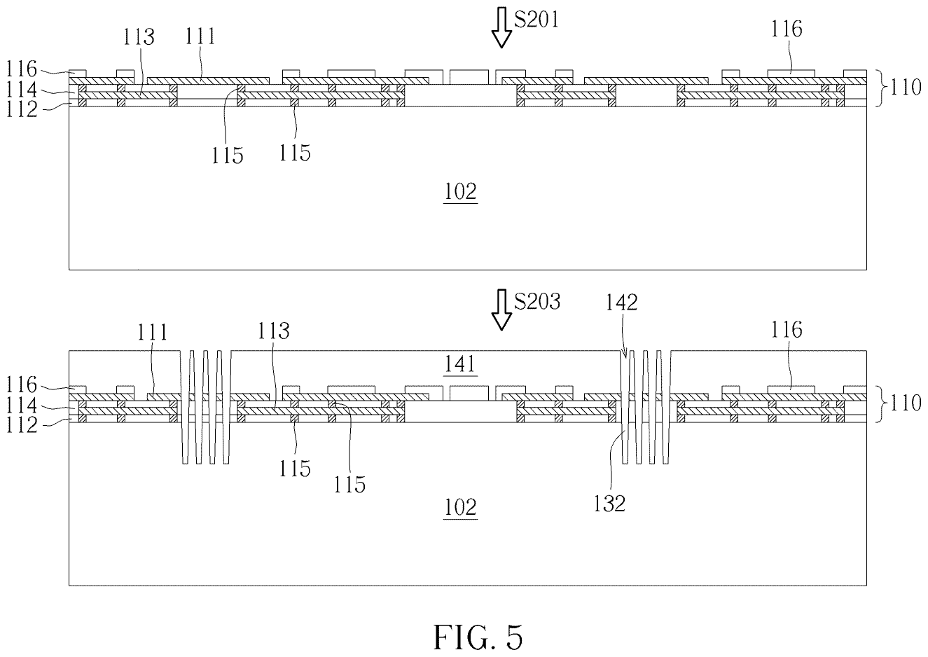

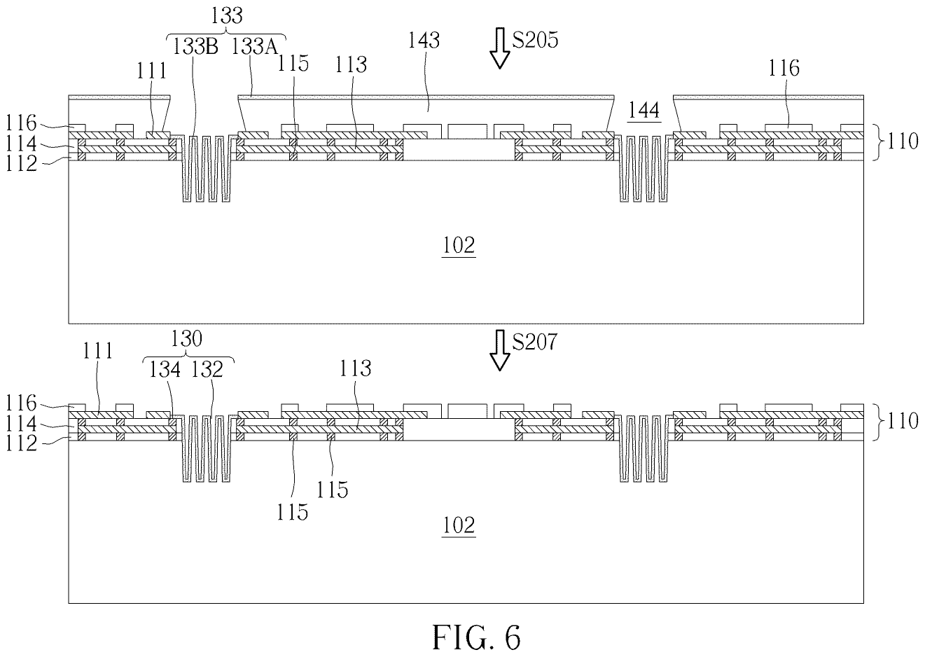

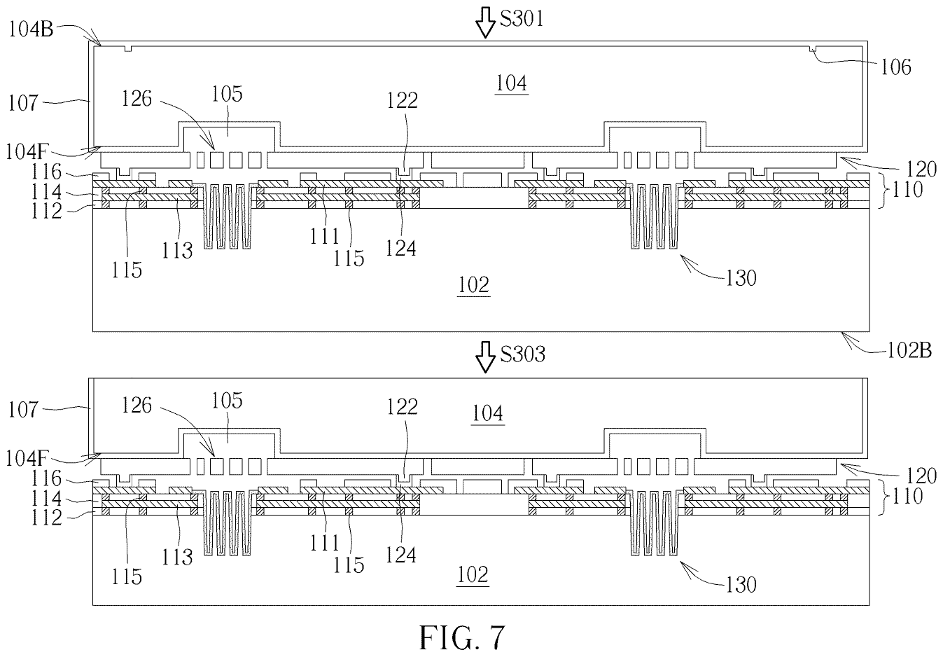

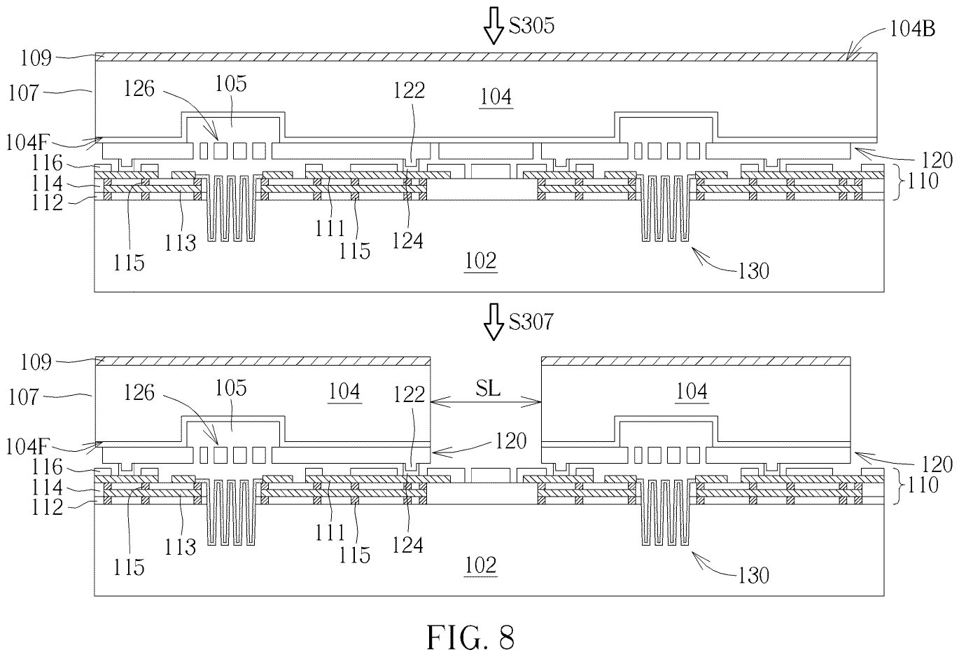

FIG. 3, FIG. 4, FIG. 5, FIG. 6, FIG. 7 and FIG. 8 are schematic cross-sectional views of some stages of a method of fabricating a MEMS package 100 according to one embodiment of the present disclosure. Referring to FIG. 3, in step S101, firstly, a second substrate 104, such as a silicon wafer, is provided as a handle wafer and polished on its front side 104F and back side 104B. Then, multiple marks 106 are formed by patterning and etching on the back side 104B of the second substrate 104. Next, multiple cavities 105 are formed in the second substrate 104 by patterning and etching its front side 104F. The depth of the cavities 105 may be about 18 μm to about 22 μm. Thereafter, a bonding layer 107 is conformally formed on the second substrate 104 and in the cavities 105, wrapping around the second substrate 104. The composition of the bonding layer 107 may be silicon oxide. The bonding layer 107 may be formed by thermal oxidation or deposition. The thickness of the bonding layer 107 may be about 1.0 μm to about 1.2 μm.

Still referring to FIG. 3, in step S103, a device wafer 119 such as a silicon wafer is provided and polished on its front side 119F. In one embodiment, the device wafer 119 is heavily doped with boron to achieve a resistivity of 0.008 to 0.02 ohm-cm. Then, the device wafer 119 is trimmed at its edges on the front side 119F and bonded to the second substrate 104 by fusion bonding, through the bonding layer 107 without plasma treatment, to cover the cavities 105. Next, referring to FIG. 3, in step S105, the device wafer 119 is thinned by grinding on its back side 119B to form a MEMS device layer 120, and a chemical-mechanical polish (CMP) process is performed on the MEMS device layer 120. After the CMP process, the MEMS device layer 120 has a thickness of about 29.5 μm to about 34.5 μm.

Next, referring to FIG. 4, in step S107, the MEMS device layer 120 is patterned by photolithography and etching processes to form seal rings 122. The seal ring 122 is a standoff structure with a height of about 2.15 μm to about 2.55 μm. Stilling referring to FIG. 4, in step S109, a bonding material 123 such as germanium (Ge) is formed on the seal rings 122 by deposition, patterning and etching processes. Then, still referring to FIG. 4, in step S111, the MEMS device layer 120 is patterned by photolithography and etching processes to form MEMS devices 126 surrounded by the seal ring 122 and directly above the cavities 105. In one embodiment, the MEMS devices 126 may be gyroscopes. Moreover, pre-cut lines 128 are formed by etching in the MEMS device layer 120 between adjacent MEMS devices 126. The MEMS device layer 120 in step S111 may be referred to as an actuator layer.

Referring to FIG. 5, in step S201, a first substrate 102 such as a CMOS wafer is provided with multiple CMOS transistors formed therein. Then, an interconnect layer 110 is formed on the first substrate 102. In one embodiment, the interconnect layer 110 includes a first IMD layer 112, a second-to-last metal layer 113, a second IMD layer 114, a top metal layer 111 and a passivation layer 116 stacked in sequence from bottom to top. Moreover, multiple vias 115 are formed in the first IMD layer 112 and the second IMD layer 114. The top metal layer 111 and the second-to-last metal layer 113 may be Aluminum (Al) layers, and formed by deposition and patterning. The first IMD layer 112 and the second IMD layer 114 may be silicon oxide layers, and formed by deposition. The vias 115 may be tungsten (W), and formed by etching and filling processes. The passivation layer 116 may be silicon nitride layer. The passivation layer 116 is formed by deposition and etching to have multiple openings to expose portions of the top metal layer 111 for seal ring bonding, bond pads, and corresponding to the MEMS devices 126. The interconnect layer 110 is electrically coupled to the CMOS transistors in the first substrate 102.

Still referring to FIG. 5, in step S203, a patterned mask 141 is formed on the interconnect layer 110. The patterned mask 141 has multiple openings 142 corresponding to a predetermined forming area of multiple trenches 132 in a getter structure. Then, multiple trenches 132 are formed in the interconnect layer 110 and the first substrate 102 by a deep reactive ion etching (DRIE) process through the openings 142 of the patterned mask 141. In one embodiment, the area of the interconnect layer 110 for forming the trenches 132 includes the top metal layer 111, the second IMD layer 114, and the first IMD layer 112 without the second-to-last metal layer 113. The trenches 132 are formed by etching to pass through the top metal layer 111, the second IMD layer 114, and the first IMD layer 112, and extend downwards into the first substrate 102. Each of the trenches 132 has an aspect ratio of about 5 to 20. The depth of the trenches 132 may be about 5 μm to about 10 μm. The DRIE process may use etching gases of SF₆ and Cl₂ to etch silicon oxide of these IMD layers, silicon of the first substrate 102 and Al of the top metal layer 111. The composition of the patterned mask 141 may be photoresist, metal or silicon nitride. Afterwards, the patterned mask 141 is removed by stripping or ashing process. In one embodiment, portions of the top metal layer 111 between the trenches 132 may be removed, along with the patterned mask 141. In another embodiment, portions of the top metal layer 111 between the trenches 132 may be remained on the second IMD layer 114.

Next, referring to FIG. 6, in step S205, a patterned negative photoresist 143 is formed on the interconnect layer 110. The patterned negative photoresist 143 has openings 144 to expose the trenches 132 and an area of the interconnect layer 110. Then, a getter material 133 such as Ti is deposited by evaporation on the patterned negative photoresist 143, on the area of the interconnect layer 110 and conformally deposited in the trenches 132. The thickness of the getter material 133 is, for example, about 1 μm to about 2 μm. The patterned negative photoresist 143 has a reentrant profile, and the opening 144 has an inverted trapezoidal cross section. Therefore, the getter material 133 is not deposited on the sidewalls of the opening 144, nor on a partial area of the interconnect layer 110 shielded by the patterned negative photoresist 143. A portion 133A of the getter material 133 is deposited on the patterned negative photoresist 143. Another portion 133B of the getter material 133 is conformally deposited on the sidewalls and the bottom surface of the trenches 132, and on a portion of the interconnect layer 110.

Thereafter, still referring to FIG. 6, in step S207, the patterned negative photoresist 143 and the portion 133A of the getter material 133 are removed together by stripping with N-Methyl-2-pyrrolidone (NMP) solvent. The portion 133B of the getter material 133 remains as a getter layer 134, formed by a lift-off process. The trenches 132 and the getter layer 134 constitute a getter structure 130 with a high aspect ratio (e.g., 5 to 20), thereby enhancing the getter absorption area.

Referring to FIG. 7, in step S301, the structure in step S111 of FIG. 4 is inverted, and the seal ring 122 of the MEMS device layer 120 is bonded to the interconnect layer 110 at a bonding temperature of about 450° C. by an eutectic bonding material 124, which includes Ge from the bonding material 123 and Al from the top metal layer 111. After the MEMS device layer 120 is bonded to the interconnect layer 110, the getter structure 130 is located directly below both the MEMS device 126 and the cavity 105. The getter material of the getter structure 130 has a getter activation temperature of about 150° C. to about 450° C., which is lower than or equal to the bonding temperature of the eutectic bonding material 124. After the MEMS device layer 120 is bonded to the interconnect layer 110, the getter structure 130 is activated to absorb the gases in the cavity 105, thereby reducing the pressure in the cavity 105 to provide high vacuum for the MEMS devices 126 such as gyroscopes. Moreover, the getter layer 134 is activated to absorb the outgassed gases from the MEMS device 126, the interconnect layer 110 and the first substrate 102. The getter structure 130 with a high aspect ratio can enhance the getter absorption surface area, thereby effectively absorbing the gases to satisfy the high-vacuum requirements of the MEMS devices 126.

Still referring to FIG. 7, in step S303, firstly, the structure in step S301 is inverted, and the first substrate 102 is thinned by grinding on its back side 102B to achieve a thickness of about 280 μm to about 300 μm. Then, the structure is inverted again, and the second substrate 104 is thinned by grinding on its back side 104B. The bonding layer 107 on the back side 104B and on partial sidewalls of the second substrate 104 is also removed by the grinding process. Afterwards, the overall thickness of the second substrate 104 and the MEMS device layer 120 may be about 200 μm to about 220 μm.

Next, referring to FIG. 8, in step S305, firstly, the second substrate 104 is trimmed at its edges, such that the bonding layer 107 on the sidewalls of the second substrate 104 is removed. Then, a metal layer 109 is deposited on the back side 104B of the second substrate 104. The metal layer 109 may be Al layer, and used for radio frequency (RF) shielding and/or electrical grounding. The thickness of the metal layer 109 may be about 0.7 μm to about 0.9 μm.

Then, still referring to FIG. 8, in step S307, parts of the second substrate 104 and parts of the MEMS device layer 120 at scribe lines SL are removed by blade saw. Thereafter, the interconnect layer 110 and the first substrate 102 are diced at the scribe lines SL to complete the MEMS package 100 of FIG. 1.

According to the embodiments of the present disclosure, the MEMS packages include a getter structure with a high aspect ratio of about 5 to 20, thereby enhancing the getter absorption area for MEMS devices requiring high vacuum. In the MEMS packages, the high-vacuum requirements of the MEMS devices are satisfied without increasing the cavity depth in the second substrate (cap wafer). The getter structure includes multiple trenches formed by etching to pass through the interconnect layer and extend downwards into the first substrate, thereby achieving a high aspect ratio. The getter layer is conformally deposited in the trenches and on the interconnect layer, thereby effectively absorbing the outgassed gases in the MEMS packages. The getter layer is formed by deposition and lift-off processes. The formation of the getter structure is compatible with interconnect and CMOS wafer fabrication. The getter structure is integrated into the interconnect layer and the first substrate (CMOS wafer), which is helpful for electrode gap control of the MEMS packages.

Moreover, the getter activation temperature of the getter structure is lower than or equal to the bonding temperature of the MEMS device layer bonded to the interconnect layer. Therefore, the activation of the getter structure is compatible with the bonding process of the MEMS package fabrication.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A micro-electro-mechanical system (MEMS) package, comprising:
a first substrate;
an interconnect layer, disposed on the first substrate;
a getter structure, disposed in both the interconnect layer and the first substrate, comprising:
a plurality of trenches, passing through the interconnect layer and extending downwards into the first substrate; and
a getter layer, conformally disposed in the plurality of trenches and on the interconnect layer;
a MEMS device layer, bonded to the interconnect layer; and
a second substrate, including a cavity, bonded to the MEMS device layer.

2. The MEMS package of claim 1, wherein the MEMS device layer includes a gyroscope, and the getter structure is located directly below the gyroscope.

3. The MEMS package of claim 1, wherein the getter structure has an aspect ratio of 5 to 20.

4. The MEMS package of claim 1, wherein the plurality of trenches have a depth of 5 μm to 10 μm.

5. The MEMS package of claim 1, wherein the getter structure is located in an area of the interconnect layer, and the getter layer is continuous in the area.

6. The MEMS package of claim 5, wherein the area of the interconnect layer comprises a plurality of inter-metal dielectric layers, and the plurality of trenches pass through the plurality of inter-metal dielectric layers.

7. The MEMS package of claim 1, wherein interconnect layer comprises a top metal layer, and the getter layer is in direct contact with the top metal layer.

8. The MEMS package of claim 1, wherein a composition of the getter layer comprises Ti, a Ti-based alloy, a Zr-based alloy, a Zr—V-based alloy or a Zr—Co-based alloy.

9. The MEMS package of claim 1, wherein the getter structure is located directly below the cavity of the second substrate.

10. The MEMS package of claim 1, wherein the first substrate includes a plurality of complementary metal oxide semiconductor (CMOS) transistors therein, and the interconnect layer is electrically coupled to the plurality of CMOS transistors.

11. A method of fabricating a micro-electro-mechanical system (MEMS) package, comprising:
providing a first substrate;
forming an interconnect layer on the first substrate;
forming a getter structure in both the interconnect layer and the first substrate;
providing a second substrate with a cavity formed therein;
forming a MEMS device layer, bonding to the second substrate and covering the cavity; and
bonding the MEMS device layer to the interconnect layer.

12. The method of claim 11, wherein the getter structure has an aspect ratio of 5 to 20.

13. The method of claim 11, wherein forming the getter structure comprises:
forming a plurality of trenches to pass through the interconnect layer and extend downwards into the first substrate; and
conformally forming a getter layer in the plurality of trenches and on the interconnect layer.

14. The method of claim 13, wherein forming the plurality of trenches comprises:
forming a patterned mask on the interconnect layer; and
etching the interconnect layer and the first substrate by a deep reactive ion etching process through openings of the patterned mask.

15. The method of claim 13, wherein the getter layer is formed by a lift-off process, comprising:
forming a patterned negative photoresist on the interconnect layer to expose the plurality of trenches and an area of the interconnect layer;
depositing a getter material on the patterned negative photoresist, on the area of the interconnect layer and conformally in the plurality of trenches; and
removing the patterned negative photoresist and the getter material on the patterned negative photoresist.

16. The method of claim 15, wherein the getter material comprises Ti, a Ti-based alloy, a Zr-based alloy, a Zr—V-based alloy or a Zr—Co-based alloy.

17. The method of claim 11, wherein the MEMS device layer is bonded to the interconnect layer at a bonding temperature, and the getter structure has a getter activation temperature lower than or equal to the bonding temperature.

18. The method of claim 11, wherein the MEMS device layer is patterned by etching to form a gyroscope, and the getter structure is located directly below the gyroscope.

19. The method of claim 11, wherein the getter structure is located directly below the cavity of the second substrate, and a pressure of the cavity is lowered by activating the getter structure after the MEMS device layer is bonded to the interconnect layer.

20. The method of claim 11, wherein the first substrate includes a plurality of complementary metal oxide semiconductor (CMOS) transistors formed therein, and the interconnect layer is electrically coupled to the plurality of CMOS transistors.
